(19) United States
(12) Patent Application Publication
(10) Pub. No.: US 2019/0383645 A1
(43) Pub. Date: Dec. 19, 2019

(54) INITIALIZATION STATE DETERMINATION OF A MAGNETIC MULTI-TURN SENSOR

(71) Applicant: Analog Devices Global Unlimited Company, Hamilton (BM)

(72) Inventors: Peter James Tonge, Newbury (GB); Monsoon Dutt, London (GB); Michael Mueller-Aulmann, Niedererbach (DE)

(21) Appl. No.: 16/007,794

(22) Filed: Jun. 13, 2018

(51) Int. Cl. G01D 5/16; B82Y 25/00; G01R 33/09

(52) U.S. Cl. CPC G01D 5/16; G01R 33/095; G01R 33/091; B82Y 25/00

(57) ABSTRACT

The disclosure relates to a method of determining the initialization state of a multi-turn sensor based on the sensor outputs. The method takes a reading of the sensor outputs, and then determines whether the sensor outputs are feasible based on an assumption that the sensor is initialised in one of two states. If the sensor outputs are correct, this initial assumption is taken to also be correct. However, if an incorrect sensor output is read, then it is taken that the assumed initialization state is incorrect. The sensor is therefore taken to be initialised in the alternative state. The method will then determine whether the sensor outputs are feasible based on this second assumption, and if an incorrect sensor output is still being read, then there is a fault in the multi-turn sensor.

### FIELD OF DISCLOSURE

The present disclosure relates to a method and device for determining the initialization state of a magnetic multi-turn sensor.

### BACKGROUND

Magnetic multi-turn sensors are commonly used in applications where there is a need to monitor the number of times a device has been turned. One example is a steering wheel in a vehicle. Magnetic multi-turn sensors often include giant magnetoresistance (GMR) elements that are sensitive to an applied external magnetic field. The resistance of the GMR elements can be changed by rotating the magnetic field within the vicinity of the sensor. Variations in the resistance of the GMR elements can be tracked to determine the number of turns in the magnetic field, which can be translated to a number of turns in the device being monitored.

To measure the changes in resistance, the GMR elements are electrically connected, for example, in a Wheatstone bridge configuration, to provide a plurality of sensor outputs. Before the sensor is used, the GMR elements are typically magnetically initialised into one of two states, such that all the sensor outputs will be the same at zero turns of the magnetic field. This is called the initialization state, and defines the state of the GMR elements at zero turns of the magnetic field. It can be important to know the initialization state in order to accurately count the number of turns, and to ensure that the sensor is working correctly and without faults. However, sensors are commonly initialised at the factory, and therefore the initialization state is often unknown when the device is first powered up. Similarly, if a sensor has been powered off and then powered back on, there can be no way of knowing what the initialization state is unless this information has been stored separately.

### SUMMARY OF THE DISCLOSURE

The disclosure relates to a method of determining the initialization state of a multi-turn sensor based on the sensor outputs. The method takes a reading of the sensor outputs, and then determines whether the sensor outputs are feasible based on an assumption that the sensor is initialised in one of two states. In this respect, the readings may be taken after any number of turns of the magnetic field, including zero turns. If the sensor outputs are correct, this initial assumption is taken to also be correct. However, if an incorrect sensor output is read, then it is taken that the assumed initialization state is incorrect. The sensor is therefore taken to be initialised in the alternative state. The method will then determine whether the sensor outputs are feasible based on this second assumption, and if an incorrect sensor output is still being read, then there is a fault in the multi-turn sensor.

In a first aspect, the present disclosure provides a method of determining initialization state of a magnetic multi-turn sensor, wherein the magnetic multi-turn sensor comprises a magnetic strip comprising a plurality of magnetoresistive elements electrically coupled in series, each of the magnetoresistive elements of the magnetic strip having at least two states, each state having an associated resistance, wherein the method comprises determining a first set of states of the plurality of magnetoresistive elements, and determining an actual initialization state of the magnetic multi-turn sensor in dependence on the first set of states.

The first set of states may be determined in response to a magnetic field rotating relative to the magnetic strip, and can be determined after any number of turns of the magnetic field. As such, the first set of states may include a first sequence of states obtained from one or more turns of the magnetic field. However, the first set of states may also be determined before any rotation in the magnetic field has occurred, that is, the states of the magnetoresistive elements at zero turns of the magnetic field.

The initialization state defines an initial set of states of the plurality of magnetoresistive elements prior to rotation of the magnetic field. The state of each of the magnetoresistive elements, wherein the state corresponds to their magnetic alignment, is sensitive to changes in an applied magnetic field. As such, the initialization state defines the initial magnetic alignment of the magnetoresistive elements before a magnetic field is rotated and the magnetic alignment of one or more of the magnetoresistive elements is changed. That is to say, the initialization state defines the set of states that would be obtained before any rotation in the magnetic field has occurred, as well as those obtained in response to rotation of the magnetic field.

The initialization state can define the states of the plurality of magnetoresistive elements at zero turns of the magnetic field. In doing so, the initialization state thereby defines the magnetic alignment of the magnetoresistive elements at zero turns of the magnetic field, and at each subsequent turn of the magnetic field thereafter. That is to say, the initialization state defines the set of states that would be obtained at zero turns of the magnetic field has occurred, as well as those obtained after each subsequent turn.

The step of determining can comprise determining that the actual initialization state is a first initialization state if the first set of states corresponds to an expected set of states for the first initialization state, and determining that the actual initialization state is a second initialization state if the first set of states deviates from the expected set of states for the first initialization state. As such, if the first set of states is different from what would be expected for a magnetic multi-turn sensor that has been initialised in the first initialization state, then it is taken that the actual initialization state cannot be the first initialization state.

In more detail, the step of determining that the actual initialization state is a second initialization state can comprise detecting a false state if one or more of the first set of states deviates from the expected set of states for the first initialization state.

The step of determining that the actual initialization state is a second initialization state can further comprise determining that the actual initialization states is the second initialization state if the first set of states corresponds to an expected set of states for the second initialization state. As such, if the first set of states matches what would be expected for a magnetic multi-turn sensor that has been initialised in the second initialization state, then it is taken that the actual initialization state is the second initialization state.

The method can further comprise detecting a fault in the magnetic multi-turn sensor if the first set of states deviates from the expected set of states for the second initialization state. As such, if the first set of states is different from what would be expected for a magnetic multi-turn sensor that has been initialised in the second initialization state, then it is taken that there is a fault in the magnetic multi-turn sensor.

The step of determining a first set of states can comprise measuring at least one output of one or more electrical connections, each electrical connection being electrically coupled to at least two magnetoresistive elements, and determining a state of the respective magnetoresistive elements from the at least one output. As the resistance of each magnetoresistive element depends on its magnetic state, the states of the magnetoresistive elements can be determined by taking resistance measurements at various points within the magnetic strip.

It will be appreciated that the magnetoresistive elements may be electrically connected in any suitable way such that the magnetic state of the individual magnetoresistive elements, and any changes therein, may be determined in some way. For example, the magnetoresistive elements may be electrically connected in a matrix configuration, wherein the magnetic states of the magnetoresistive elements may be determined by comparing the measured resistances to that of a reference magnetoresistive element.

The method can also comprise generating a domain wall at an end of the magnetic strip in response to a magnetic field rotating 180° to thereby cause a magnetoresistive element to change state. In this respect, a new domain wall can be generated with every 180° rotation of the magnetic field. As each domain wall is generated, it can be injected into the magnetic strip such that it propagates therealong, changing the state of each magnetoresistive element as it travels past.

The method can further comprise decoding a half-turn count of a rotating magnetic field based on the first set of states and the determined actual initialization state. As discussed above, knowledge of the initialization state is desired in order to accurately decode the number of 180° turns of the magnetic field based on the states of the magnetoresistive elements. In this respect, the method can further comprise storing the determined initialization state, for example, in some suitable storage means or memory. The stored initialization state may then be used at a later date, for example, to perform the step of decoding the half-turn count of a rotating magnetic field.

In a further aspect, the present disclosure provides a device for determining the initialization state of a magnetic multi-turn sensor, wherein the magnetic multi-turn sensor comprises a magnetic multi-turn strip comprising a plurality of magnetoresistive elements electrically coupled in series, each of the magnetoresistive elements of the magnetic strip having at least two states, each state having an associated resistance, wherein the device is configured to determine a first set of states of the plurality of magnetoresistive elements, and determine an actual initialization state of the magnetic multi-turn sensor in dependence on the first set of states.

The device can be further configured to determine that the actual initialization state is a first initialization state if the first set of states corresponds to an expected set of states for the first initialization state, and determine that the actual initialization state is a second initialization state if the first set of states deviates from the expected set of states for the first initialization state.

The device can be further configured to determine that the actual initialization states is the second initialization state if the first set of states corresponds to an expected set of states for the second initialization state.

The device can be further configured to detect a fault in the magnetic multi-turn sensor if the first set of states deviates from the expected set of states for the second initialization state.

In a further aspect, the present disclosure provides a magnetic multi-turn sensor system, comprising, a magnetic strip comprising a plurality of magnetoresistive elements electrically coupled in series, each of the magnetoresistive elements of the magnetic strip having at least two states, each state having an associated resistance, a plurality of electrical connections electrically coupled to a plurality of nodes along the magnetic strip, and a device configured to determine a first set of states of the plurality of magnetoresistive elements, and determine an actual initialization state of the magnetic strip in dependence on the first set of states.

The device can be further configured to measure at least one output of the plurality of electrical connections, and determine a state of the respective magnetoresistive elements from the at least one output.

The magnetic strip can have a spiral configuration comprising strip corners, and strip sides having a variable resistance, wherein the plurality of magnetoresistive elements comprise the sides, and wherein the plurality of nodes comprise the strip corners.

The system can further comprise a domain wall generator coupled to a first end of the plurality of magnetoresistive elements, the domain wall generator being configured to generate a domain wall at a corner in the magnetic strip to thereby cause a magnetoreistive element to change state.

The system can further comprise a magnet arranged so as to cause the domain wall generator to change domain walls in the plurality of magnetoresistive elements, such that the resistance of at least one magnetoresistive element changes in response to the magnetic multi-turn rotating 180°.

In yet a further aspect, the present disclosure provides a computer system comprising a processor, and a computer readable medium storing one or more instruction(s) arranged such that when executed the processor is caused to perform a method of determining initialization state of a magnetic multi-turn sensor, wherein the magnetic multi-turn sensor comprises a magnetic strip comprising a plurality of magnetoresistive elements electrically coupled in series, each of the magnetoresistive elements of the magnetic strip having at least two states, each state having an associated resistance, and wherein the method comprises determining a first set of states of the plurality of magnetoresistive elements, and determining an actual initialization state of the magnetic multi-turn sensor in dependence on the first set of states.

Further features of the disclosure are defined in the appended claims.

### BRIEF DESCRIPTION OF THE DRAWINGS

The teachings of this disclosure will be discussed, by way of non-limiting examples, with reference to the accompanying drawings, in which:

FIG. 1 is a schematic block diagram of an example magnetic multi-turn sensor system that includes a multi-turn sensor;

FIG. 2 shows an example multi-turn sensor having a Wheatstone bridge configuration;

FIGS. 3A-3J show an example of progressive turn states of an example multi-turn sensor as an external magnetic field rotates; and

FIG. 4 is a flow diagram illustrating the process of decoding the initialization state from an output of a multi-turn sensor according to an embodiment.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Magnetic multi-turn sensors can be used to monitor the turn count of a rotating shaft. Such magnetic sensing can be applied to a variety of different applications, such as automotive applications, medical applications, industrial control applications, consumer applications, and a host of other applications which desire information regarding a position of a rotating component. The present disclosure provides a method of determining the initialization state of a magnetic multi-turn sensor based on the outputs of the sensor itself. The initialization state acts as the starting point from which turn count is determined, and so knowledge of the initialization state is desired for accurately counting the number of turns in a rotating magnetic field. However, this information is not always available, for example, the sensor may have been initialized at the factory or powered off without the initialization state being stored. The method enables the initialization state to be determined without any prior knowledge of the sensor, which means that the sensor can be powered up and used straight away to count the number of turns in a magnetic field without any prior testing.

To determine the initialization state, the method uses a set of sensor outputs obtained at any stage during the rotation of an external magnetic field within the vicinity of the sensor. In this respect, the sensor outputs corresponding to zero turns of the magnetic field may also be used to determine the initialization state. The method will first assume that the sensor has been initialized into a particular state, where the sensor may be initialized into one of two different states. If based on that first assumption the sensor outputs are as expected, the first assumption is taken to be the correct assumption. However, if any of the sensor outputs appear to deviate from what is expected, the first assumption is taken to be incorrect. The method will then assume that the sensor has been initialized into the alternative state. If based on this new assumption the sensor outputs are as expected, the second assumption is taken to be the correct assumption. However, if any of the sensor outputs still appear to deviate from what is expected, then the sensor must have a fault.

As the method can use the same sensor outputs as those used to determine the turn count, the initialization state may be automatically determined immediately before or at the same time as the turn count is being measured. Similarly, the initialization state may be determined and saved for future use. In some instances, the initialization state can be stored to non-volatile memory. According to certain applications, the initialization state can be determined and stored in response to a device being activated and/or powered on.

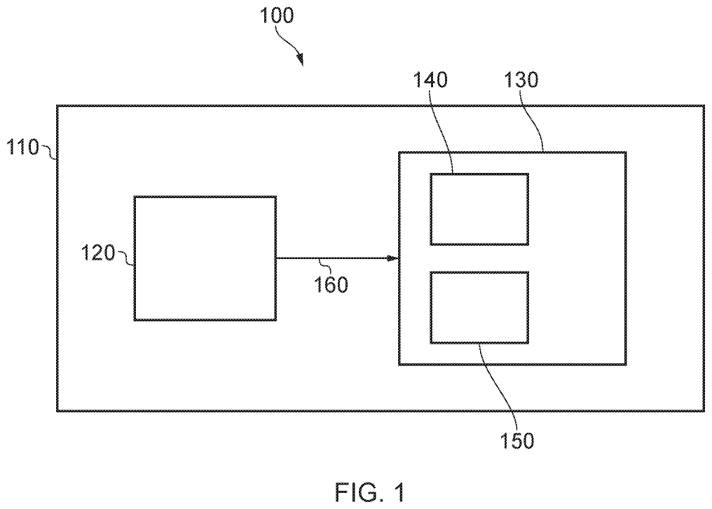

FIG. 1 is a schematic block diagram of an example magnetic multi-turn sensor system 100 that includes a multi-turn (MT) sensor 120. The magnetic multi-turn sensor system 100 also includes a processing circuit 130, and an integrated circuit 110 on which the MT sensor 120 and processing circuit 130 are disposed. The processing circuit 130 can include any suitable circuitry (e.g., digital circuitry and/or analog circuitry) to perform the functions described herein. The processing circuit 130 receives signals S_{M} 160 from the MT sensor 120 and processes the received signals to determine the initialization state using an initialization state decoder 140, as will be discussed in more detail below. The initialization state decoder 140 may output the determined initialization state to a turn count decoder 150, which will process the signals received from the MT sensor 120, along with the determined initialization state, to output a turn count representative of the number of turns of an external magnetic field (not shown) rotating in the vicinity of the MT sensor 120. As will be discussed below, the initialization state decoder 140 is also configured to detect a fault in the MT sensor 120 and output a signal indicative thereof.

The processing circuit 130 can implement a method to determine the initialization state from the signals S_{M} 160 of the MT sensor 120. The processing circuit 130 can be implemented by any suitable electronic circuity configured to determine the initialization state.

It will also be appreciated that the method of determining the initialization state may be implemented on some other external processing means, such as a processing circuit or system. For example, a separate computing device (not shown) having a processor and a computer readable storage medium for storing instructions that, when executed by the processor, cause the processor to determine the initialization state based on the signals S_{M} 160 received from the MT sensor 120 via a wired or wireless connection.

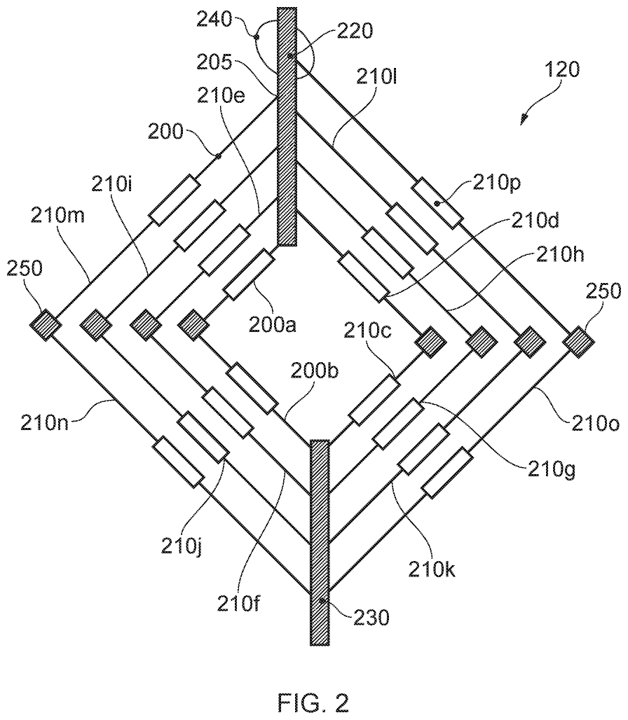

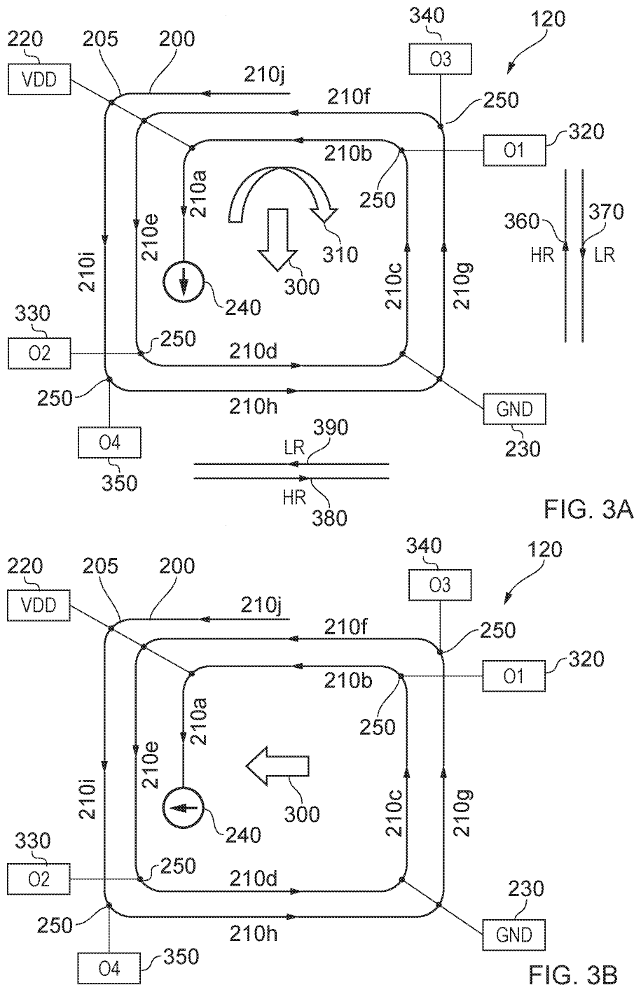

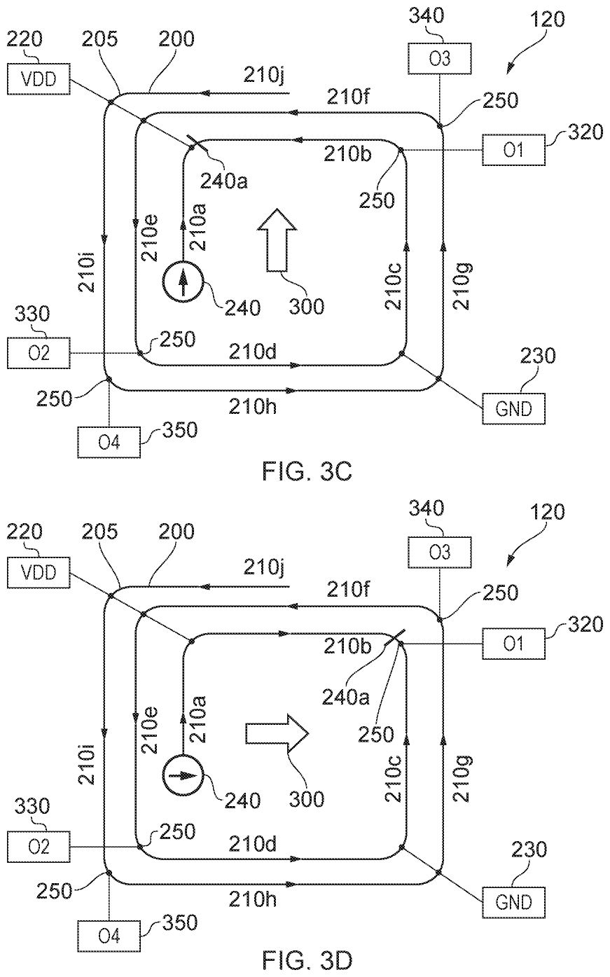

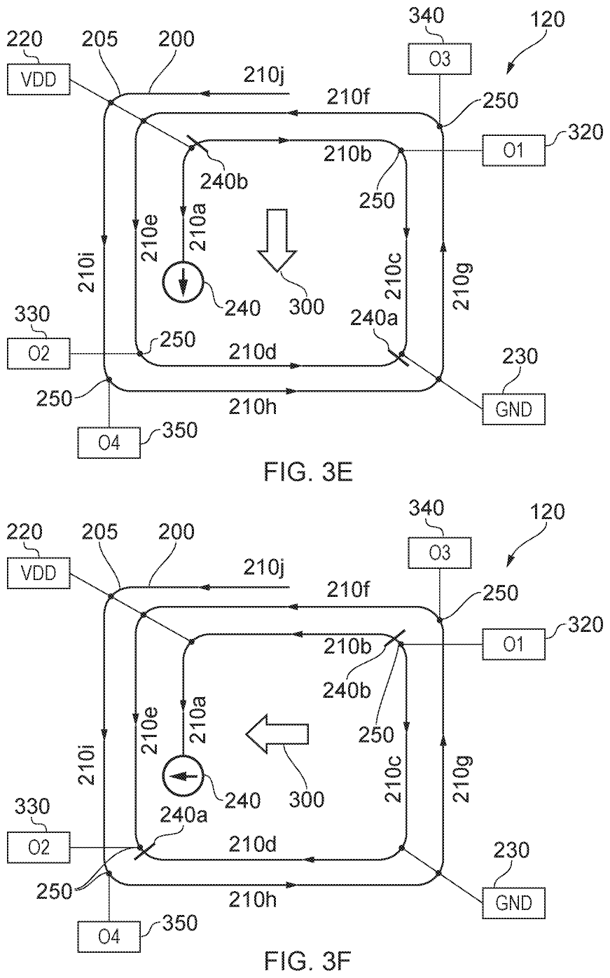

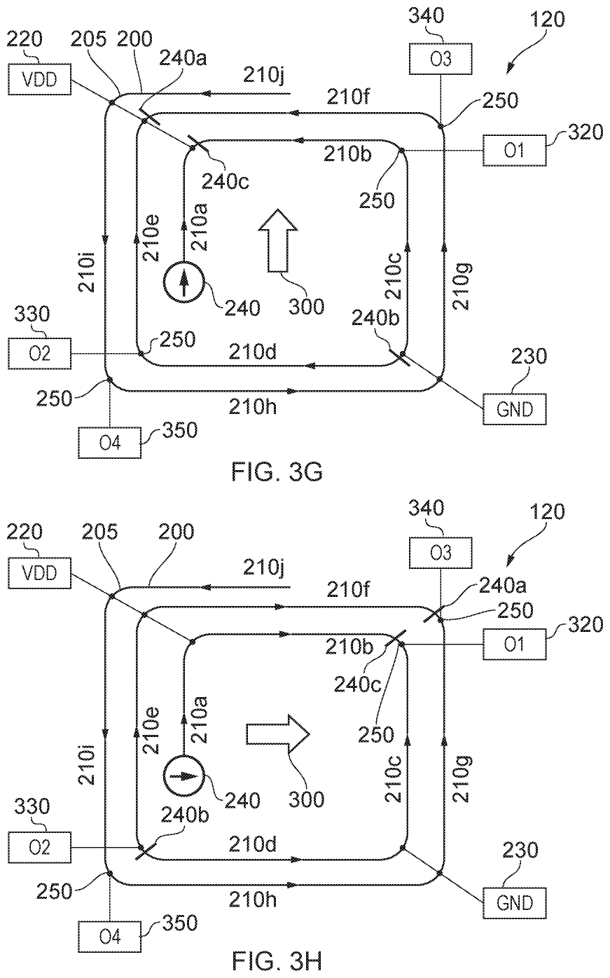

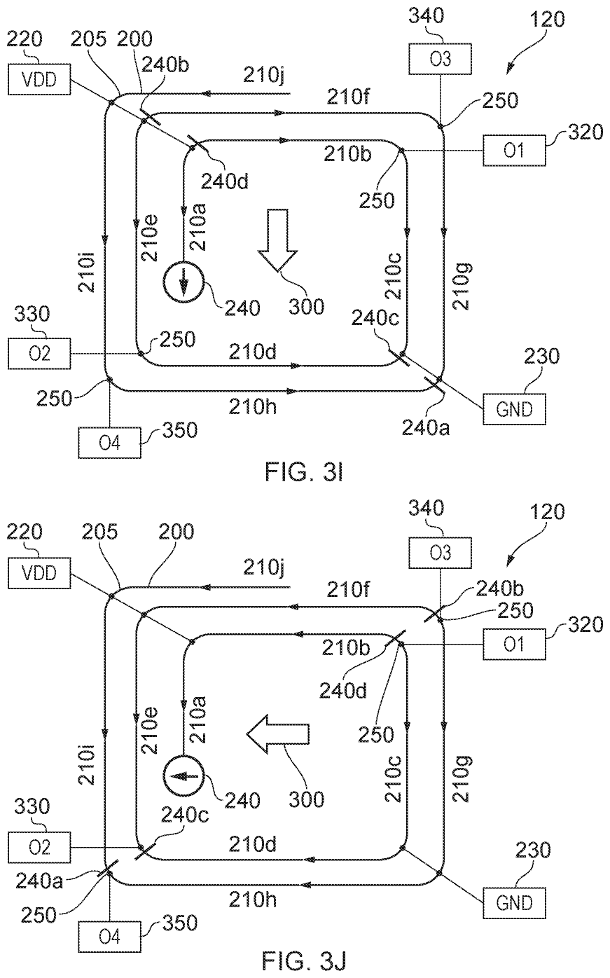

An example of an MT sensor 120 and its mode of operation is shown by FIGS. 2 and 3a-j.

FIG. 2 shows an example of a magnetic strip layout representation of a MT sensor 120 connected in a Wheatstone bridge configuration. In the example of FIG. 2, the magnetic strip 200 is a giant magnetoresistance track that is physically laid out in a spiral configuration. As such, the magnetic strip 200 has corners 205 and segments 210a to 210p, the segments 210a-p being formed of magnetoresistive elements arranged in series with each other. The magnetoresistive segments 210a-p act as variable resistors that change resistance in response to a magnetic alignment state. One end of the magnetic strip 200 is coupled to a domain wall generator (DWG) 240. In this respect, it will be appreciated that the DWG 240 may be coupled to either end of the magnetic strip 200. The DWG 240 generates domain walls in response to rotations in an external magnetic field, or the application of some other strong external magnetic field beyond the operating magnetic window of the sensor 120. These domain walls can then be injected into the magnetic strip 200. As the magnetic domain changes, the resistance of the segments 210a-p will also change due to the resulting change in magnetic alignment. This will be discussed in more detail below with reference to FIGS. 3A-3J.

In order to measure the varying resistance of the magnetoresistive segments 210a-p as domain walls are generated, the magnetic strip 200 is electrically connected to a supply voltage VDD 220 and to ground GND 230 to apply a voltage between a pair of opposite corners 205. The corners 205 half way between the voltage supplies are provided with electrical connections 250 so as to provide half-bridge outputs. As such, the MT sensor 120 comprises multiple Wheatstone bridge circuits, with each half-bridge 250 corresponding to one half-turn or 180° rotation of an external magnetic field, as will be discussed in more detail below. Measurements of voltage at the electrical connections 250 can thus be used to measure changes in the resistance of the magnetoresistive segments 210a-p, which are indicative of changes in their magnetic alignment.

The example shown by FIG. 2 comprises eight half-bridges 250, and is thus configured to count four turns of an external magnetic field. However, it will be appreciated that an MT sensor may have any number of half-bridges depending on the number of magnetoresistive segments. In general, MT sensors can count half as many turns as half-bridges.

It will also be appreciated that the magnetoresistive segments 210a-p may be electrically connected in any suitable way so as to provide sensor outputs representative of the changes in magnetic alignment state. For example, the magnetoresistive segments 210a-p may be connected in a matrix arrangement such as that described in US 2017/0261345, which is hereby incorporated by reference in its entirety. As a further alternative, each magnetoresistive segment may be connected individually, rather than in a bridge arrangement.

FIGS. 3A-3J show an example of the progressive turn states of an example multi-turn sensor as a magnetic field rotates. As in the example of FIG. 2, the multi-turn sensor 120 has a magnetic strip layout, with magnetoresistive segments 210a-j providing the sides of the magnetic strip 200, along with a DWG 240, a supply voltage VDD 220, a ground GND 230 and electrical connections 250 at the corners between the voltage supplies 220, 230. FIGS. 3A-3J also show an external magnetic field 300, which is to be rotated in a clockwise direction, as shown by arrow 310 in FIG. 3A. Whilst this example shows the magnetic field 300 as being rotated in a clockwise direction 310, it will be appreciated that the magnetic field 300 is rotated in the direction in which the magnetic strip 200 spirals from the DWG 240 to the opposite end of the magnetic strip 200. In this respect, the DWG 240 may be located at either end of the magnetic strip 200.

Magnetic orientations 360, 370, 380 and 390 indicate an orientation of a domain inside a segment 210a-j of the magnetic strip 200. As discussed previously, the DWG 240 can be affected by the external magnetic field 300. As the external magnetic field 300 rotates, DWG 240 can inject domain walls through magnetic strip 200, the magnetic orientations 360, 370, 380 and 390 changing as the domain walls propagate through the strip 200, as will be discussed in more detail below. The resistivity of the magnetoresistive segments 210a-j is dictated by the magnetic orientation within the segments 210a-j. In this respect, each segment's magnetic orientation can cause that segment to have a high resistance (HR) or a low resistance (LR). Vertically illustrated segments 210a-j having a magnetic orientation 360 have a higher resistivity than vertical segments 210a-j having a magnetic orientation 370, which have a low resistivity. Similarly, horizontally illustrated segments 210a-j having a magnetic orientation 380 have a higher resistivity than horizontal segments 210a-j having a magnetic orientation 390, which have a low resistivity. The segments 210a-j having magnetic orientations 360 and 380 may have comparable resistances, and segments 210a-j having magnetic orientations 370 and 390 may also have comparable resistances, although the actual resistances between segments 210a-j may vary.

As such, in this example, each sensor output 320, 330, 340, and 350 is a comparison of the resistance of the magnetoresistive segments 210b-i either side of it. In the present example, the end segments 210a and 210j are unused, however, the end segments may be used in other arrangements. Taking the first sensor output 320 as an example, the output 320 may be a high value if the resistance of the first magnetoresistive segment 210b is lower than the second magnetoresistive segment 210c, zero if the first and second magnetoresistive segments 210b-c have equal resistance, or a low value if the resistance of the first magnetoresistive segment 210b is higher than the second magnetoresistive segment 210c.

A set and/or sequence of outputs from the sensor outputs 320, 330, 340, and 350 as the external magnetic field 300 is rotated can thus be used to decode the number of turns in the magnetic field 300. As such, the number of turns in the magnetic field 300 is decoded based on a pattern in the states of the individual magnetoresistive segments 210b-i coupled to the sensor outputs 320, 330, 340, and 350, which in this example is achieved by comparing the resistances of adjacent segments. However, it will be appreciated that this may be achieved in a number of other ways depending on the configuration of the MT sensor 120. For example, in a MT sensor where the magnetoresistive segments are connected in a matrix arrangement, each magnetoresistive segment may be compared to a reference segment, and the number of turns in the magnetic field decoded from a pattern in said comparison.

In order to decode the number of turns in the magnetic field 300, the sensor 120 is initialized in one of two ways, and it is this initialization state that defines what the sensor outputs 320, 330, 340, 350 should be for each turn of the magnetic field 300. Generally, the sensor 120 can be initialised magnetically or put into a known state by filling the magnetic strip 200 with domain walls, such that the magnetic strip 200 is in a “full” state. The magnetic strip 200 can be filled with domain walls by rotating an external magnetic field in the clockwise direction (for a clockwise MT sensor) or the anti-clockwise direction (for an anti-clockwise MT sensor) for its maximum number of turns, or alternatively, by applying a strong external magnetic field beyond the operating magnetic window of the sensor, which can have the same physical effect in that it populates the magnetic strip 200 with domain walls. The initialisation state thus corresponds to the magnetic alignment of the magnetoresistive segments 210a-j when the magnetic strip 200 is full of domain walls, i.e. when the magnetic field 300 is at its maximum number of turns. This therefore defines what the magnetic alignment of the magnetoresistive segments 210a-j will be when the magnetic strip 200 contains no domain walls, i.e. the magnetic field is at zero turns, as well as the expected set and/or sequence of magnetic alignments of the magnetoresistive segments 210a-j for every turn of the magnetic field 300 therebetween. As noted above, the sensor 120 can be initialized in one of two ways, such that the sensor outputs 320, 330, 340, 350 are either all low values or high values when there are no domain walls in the magnetic strip 200, that is, the magnetic strip 200 is in an “empty” state.

FIG. 3A shows an example of the MT sensor 120 in its zero-turn count state, or “empty” state, wherein the magnetic field 300 has not yet been rotated and no domain walls are present. In the empty state of the MT sensor 120 shown in FIG. 3A, the magnetic orientations are the same along each side of the magnetic strip 200, and so all of the four sensor outputs 320, 330, 340, and 350 connected to the electrical connections 250 will be the approximately same. In the present example, the MT sensor 120 has been initialized such that the sensor outputs 320, 330, 340, and 350 all have a low value in the “empty” state, however, the sensor outputs 320, 330, 340, and 350 could instead have a high value. It will also be appreciated that the values of the sensor outputs in the empty state will depend on how the MT sensor 120 is connected.

The magnetoresistive segments 210a-j of the MT sensor 120 will stay in these magnetic orientations, that is, in their “empty” state, until a domain wall has been generated and injected into the magnetic strip 300, each magnetoresistive segment 210a-j changing magnetic orientation as the domain wall propagates past it, as will now be discussed.

FIGS. 3B and 3C show the MT sensor 120 as the magnetic field 300 is rotated through 180°. As the magnetic field 300 is rotated, a first domain wall 240a is generated and shifted past the first magnetoresistive segment 210a, thereby changing the magnetic orientation of the first segment 210a from magnetic orientation 370 to magnetic orientation 360. As the first segment 210a is unused, the first 90° turn is not counted.

As the magnetic field 300 is rotated a further 90°, as shown in FIG. 3D, the first domain wall 240a shifts past the second magnetoresistive segment 210b, again changing its magnetic orientation. In doing so, the first sensor output 320 also changes, which can then be decoded to indicate one half-turn or 180° rotation in the magnetic field 300. As the remaining magnetoresistive segments 210c-j do not contain any domain walls, their magnetic orientation stays the same, that is, they are still in their “empty” state.

FIGS. 3E and 3F show the MT sensor 120 as the magnetic field 300 is rotated through a further 180°. In doing so, a second domain wall 240b is generated and shifted past the first and second magnetoresistive segments 210a and 210b, and changes their magnetic orientation once more. The first domain wall 240a also continues to propagate past the third and fourth magnetoresistive segments 210c and 210d, changing their magnetic orientation in the process. In doing so, the first and second sensor outputs 320 and 330 change, which can then be decoded to indicate two half-turns or 360° rotation in the magnetic field 300.

FIGS. 3G and 3H show the MT sensor 120 as the magnetic field 300 is rotated through a further 180°. In doing so, a third domain wall 240c is generated and shifted past the first and second magnetoresistive segments 210a and 210b, changing their magnetic orientation. The second domain wall 240b also continues to propagate past the third and fourth magnetoresistive segments 210c and 210d, whilst the first domain wall 240a propagates past the fifth and sixth segments 210e and 210f, changing their magnetic orientation in the process. In doing so, the first, second and third sensor outputs 320, 330 and 340 change, which can then be decoded to indicate three half-turns or 540° rotation in the magnetic field 300.

FIGS. 3I and 3J show the MT sensor 120 as the magnetic field 300 is rotated through yet a further 180°. In doing so, a fourth domain wall 240d is generated and shifted past the first and second magnetoresistive segments 210a and 210b, changing their magnetic orientation. The third domain wall 240c also continues to propagate past the third and fourth magnetoresistive segments 210c and 210d, whilst the second domain wall 240b propagates past the fifth and sixth segments 210e and 210f, and the first domain wall 240a propagates past the seventh and eighth segments 210g and 210h, all changing their magnetic orientations in the process. In doing so, the first, second, third and fourth sensor outputs 320, 330, 340 and 350 change, which can then be decoded to indicate four half-turns or 720° rotation in the magnetic field 300.

If the magnetic field 300 is then rotated back in the opposite direction, which in this case would be the anti-clockwise direction, the domain walls 240a-d will propagate back along the magnetic strip 300, changing the magnetic orientations of the magnetoresistive segments 210a-j as they pass back through. In doing so, the set and/or sequence of magnetic states described with reference to FIGS. 3A-3J is effectively reversed, the magnetoresistive segments 210a-j finally returning to their “empty” state as the final domain wall 240a passes back through.

In order to correctly decode the set and/or sequence of sensor outputs 320, 330, 340 and 350 resulting from the rotation of the magnetic field 300, and hence the set and/or sequence of magnetic states, it can be important to know the initialization state of the MT sensor 120, and thus the initial magnetic orientation of each of the magnetoresistive segments 210a-p and the resulting sensor outputs 320, 330, 340 and 350 before the magnetic field 300 is rotated, or at least before rotation of the magnetic field 300 has any effect on the sensor outputs 320, 330, 340 and 350. However, information regarding the initialization state is not always available upon powering up the MT sensor 120.

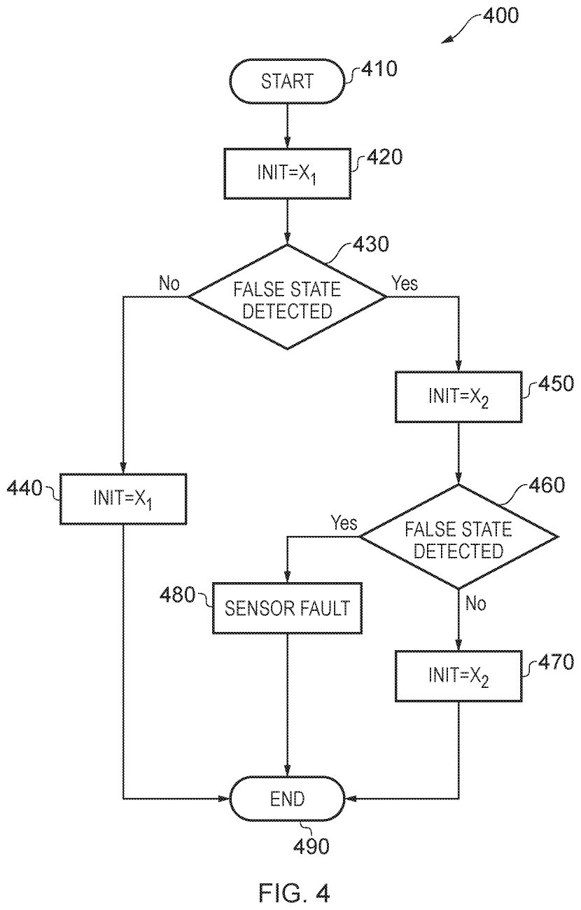

FIG. 4 is a flow diagram illustrating the process 400 of decoding the initialization state from an output of a multi-turn sensor according to an embodiment. The process 400 can be implemented by any suitable electronic circuitry configured to determine an initialization state from a MT sensor output. For example, the processing circuit 130 of FIG. 1 can include an initialization state decoder 140 arranged to implement the process 400. As another example, an initialization state decoder may be integrated with the MT sensor and provide an initialization state to a processing circuit. The process 400 can be performed in response to activating a MT sensor, for example.

The process 400 starts at step 410, wherein a set and/or sequence of sensor outputs can be obtained corresponding to a set and/or sequence of magnetic states. In this respect, the set and/or sequence of sensor outputs 320, 330, 340 and 350 may be obtained at any stage during the rotation of the magnetic field 300, including when the magnetic field 300 is at zero turns. The process 400 makes an assumption about the initialization state at step 420. In this case, the MT sensor 120 is assumed to have been initialized into a first initialization state X₁. For example, the process 400 may assume that the MT sensor 120 is initialized such that the sensor outputs 320, 330, 340 and 350 all have a low value at zero turns of the magnetic field 300. At step 430, the set and/or sequence of sensor outputs 320, 330, 340 and 350 will be processed to determine whether there would be any false states if the MT sensor 120 was initialized in the first initialization state X₁. In this respect, any method of false state detection may be used to determine whether any part of the set and/or sequence of sensor outputs 320, 330, 340 and 350 deviates from an expected set and/or sequence for the initialization state assumed at step 420.

If a false state is not detected, then the initial assumption is taken to be correct at step 440. As such, if the sensor outputs 320, 330, 340 and 350 correspond to an expected set of outputs for an MT sensor 120 initialized in the first initialization state X₁, then the first initialization state X₁ is the actual initialization state of the MT sensor 120.

If there appears to be false state in the set and/or sequence of sensor outputs 320, 330, 340 and 350, then the initial assumption is taken to be incorrect. As such, if the sensor outputs 320, 330, 340 and 350 do not correspond to an expected set of outputs for an MT sensor 120 initialized in the first initialization state X₁, then the first initialization state X₁ is not the actual initialization state of the MT sensor 120.

The assumption will then be changed at step 450, and the MT sensor 120 is instead assumed to have been initialized into a second initialization state X₂. For example, the process 400 will now assume that the MT sensor 120 is initialized such that the sensor outputs 320, 330, 340 and 350 all have a high value at zero turns of the magnetic field 300. At step 460, the set and/or sequence of sensor outputs 320, 330, 340 and 350 will be processed again to determine whether there are any false states based on the new assumption. In this respect, any method of false state detection may be used to determine whether any part of the set and/or sequence of sensor outputs 320, 330, 340 and 350 deviates from an expected set and/or sequence for the initialization state assumed at step 450.

As before, if a false state is not detected, then the second assumption is taken to be correct at step 470. As such, if the sensor outputs 320, 330, 340 and 350 correspond to an expected set of outputs for an MT sensor 120 initialized in the second initialization state X2, then the second initialization state X2 is the actual initialization state of the MT sensor 120.

However, if a false state in the set and/or sequence of sensor outputs 320, 330, 340 and 350 is detected after the second assumption has been made, then the process 400 will determine that there is a fault in the MT sensor 120 itself at step 480.

If the process 400 has determined the actual initialization state, the process 400 will end at step 490, where the determined initialization state may be output to a turn count decoder 150, as is discussed below, or some other processing circuit. The initialization state can be stored to volatile and/or non-volatile memory. Similarly, if the process 400 has detected a fault, the process will proceed to the end at step 490, where a signal indicating the sensor fault may be provided to a processing circuit.

Once the initialization state has been determined using the above process 400, the determined initialization state may be used to decode the turn count of the MT sensor 120 as an external magnetic field is rotated. For example, the processing circuit 130 of FIG. 1 can include a turn count decoder 150 arranged to output a turn count based on the determined initialization state and the sensor outputs 320, 330, 340 and 350. As another example, a turn count decoder may be integrated within the MT sensor 120 and configured to provide a turn count to a separate processing circuit.

In an embodiment, an initialization state can be determined by comparing a set of MT magnetic sensor states to two initialization states in an initialization state decoder. The set of MT magnetic sensor states can be compared to the two initialization states concurrently and/or sequentially. The initialization state decoder can provide an output signal to indicate whether the initialization state is a first initialization state, whether the initialization state is a second initialization sate, or if there is a sensor fault. As one example, the output signal can be a 3 bit signal in which a first bit indicates whether the initialization state is a first initialization state, a second bit indicates whether the initialization state is a second initialization state, and third bid indicating whether there is a sensor fault. The output signal can alternatively be a two bit signal. The output signal can be stored to memory (e.g., non-volatile memory or volatile memory) and be accessed for determining a turn count of a MT sensor.

Unless the context indicates otherwise, throughout the description and the claims, the words “comprise,” “comprising,” “include,” “including,” and the like are to generally be construed in an inclusive sense, as opposed to an exclusive or exhaustive sense; that is to say, in the sense of “including, but not limited to.” The word “coupled,” as generally used herein, refers to two or more elements that may be either directly coupled to each other, or coupled by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural may also include the plural or singular, respectively. The word “or” in reference to a list of two or more items, is generally intended to encompass all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding whether these features, elements and/or states are included or are to be performed in any particular embodiment.

While certain embodiments have been described, these embodiments have been presented by way of example only, and are not intended to limit the scope of the disclosure. Indeed, the novel methods, apparatus, systems, devices, and integrate circuits described herein may be embodied in a variety of other forms; furthermore, various omissions, substitutions and changes in the form of the methods, apparatus, and systems described herein may be made without departing from the spirit of the disclosure. For example, circuit blocks described herein may be deleted, moved, added, subdivided, combined, and/or modified. Each of these circuit blocks may be implemented in a variety of different ways. The accompanying claims and their equivalents are intended to cover any such forms or modifications as would fall within the scope and spirit of the disclosure.

The claims presented herein are in single dependency format suitable for filing at the United States Patent & Trademark Office. However it is to be assumed that each one of the claims can be multiply dependent on any preceding claim except where that is technically unfeasible.

What is claimed is:

1. A method for determining an initialization state of a magnetic multi-turn sensor, wherein the magnetic multi-turn sensor comprises a magnetic strip comprising a plurality of magnetoresistive elements electrically coupled in series, each of the magnetoresistive elements of the magnetic strip having at least two states, each state having an associated resistance, wherein the method comprises:
determining a first set of states of the plurality of magnetoresistive elements; and
determining an actual initialization state of the magnetic multi-turn sensor in dependence on the first set of states.

2. A method according to claim 1, wherein the initialization state defines an initial set of states of the plurality of magnetoresistive elements prior to rotation of a magnetic field.

3. A method according to claim 1, wherein the initialization state defines the states of the plurality of magnetoresistive elements at zero turns of a magnetic field.

4. A method according to claim 1, wherein the step of determining the actual initialization state comprises:
determining that the actual initialization state is a first initialization state if the first set of states corresponds to an expected set of states for the first initialization state; and
determining whether the actual initialization state is a second initialization state if the first set of states deviates from the expected set of states for the first initialization state.

5. A method according to claim 4, wherein the step of determining whether the actual initialization state is the second initialization state comprises detecting a false state if one or more of the first set of states deviates from the expected set of states for the first initialization state.

6. A method according to claim 4, wherein the step of determining that the actual initialization state is the second initialization state further comprises:
determining that the actual initialization states is the second initialization state if the first set of states corresponds to an expected set of states for the second initialization state.

7. A method according to claim 6, further comprises:
detecting a fault in the magnetic multi-turn sensor if the first set of states deviates from the expected set of states for the second initialization state.

8. A method according to claim 1, wherein determining a first set of states comprises:
measuring at least one output of one or more electrical connections, each electrical connection being electrically coupled to at least two magnetoresistive elements; and
determining a state of the respective magnetoresistive elements from the at least one output.

9. A method according to claim 1, wherein the method comprises generating a domain wall at an end of the magnetic strip in response to a magnetic field rotating 180° to thereby cause a magnetoresistive element to change state.

10. A method according to claim 1, further comprising:
decoding a half-turn count of a rotating magnetic field based on the first set of states and the determined actual initialization state.

11. A device for determining the initialization state of a magnetic multi-turn sensor, wherein the magnetic multi-turn sensor comprises a magnetic multi-turn strip comprising a plurality of magnetoresistive elements electrically coupled in series, each of the magnetoresistive elements of the magnetic strip having at least two states, each state having an associated resistance, wherein the device is configured to:
determine a first set of states of the plurality of magnetoresistive elements; and
determine an actual initialization state of the magnetic multi-turn sensor in dependence on the first set of states.

12. A device according to claim 11, further configured to:
determine that the actual initialization state is a first initialization state if the first set of states corresponds to an expected set of states for the first initialization state; and
determine whether the actual initialization state is a second initialization state if the first set of states deviates from the expected set of states for the first initialization state.

13. A device according to claim 12, further configured to:
determine that the actual initialization states is the second initialization state if the first set of states corresponds to an expected set of states for the second initialization state.

14. A device according to claim 13, further configured to:
detect a fault in the magnetic multi-turn sensor if the first set of states deviates from the expected set of states for the second initialization state.

15. A magnetic multi-turn sensor system, comprising:
a magnetic strip comprising a plurality of magnetoresistive elements electrically coupled in series, each of the magnetoresistive elements of the magnetic strip having at least two states, each state having an associated resistance;
a plurality of electrical connections electrically coupled to a plurality of nodes along the magnetic strip; and
a device according to claim 11.

16. A system according to claim 15, wherein the device is further configured to:
measure at least one output of the plurality of electrical connections; and
determine a state of the respective magnetoresistive elements from the at least one output.

17. A system according to claim 15, wherein the magnetic strip has a spiral configuration comprising strip corners, and strip sides having a variable resistance, wherein the plurality of magnetoresistive elements comprise the sides, and wherein the plurality of nodes comprise the strip corners.

18. A system according to claim 17, further comprising a domain wall generator coupled to a first end of the plurality of magnetoresistive elements, the domain wall generator being configured to generate a domain wall at a corner in the magnetic strip to thereby cause a magnetoreistive element to change state.

19. A system according to claim 18, further comprising a magnet arranged so as to cause the domain wall generator to change domain walls in the plurality of magnetoresistive elements, such that the resistance of at least one magnetoresistive element changes in response to the magnetic multi-turn rotating 180°.

20. A computer system comprising:
a processor; and
a computer readable medium storing one or more instruction(s) arranged such that when executed the processor is caused to perform the method of claim 1.
